(19) United States
(12) Patent Application Publication
(10) Pub. No.: US 2005/0194671 A1
(43) Pub. Date: Sep. 8, 2005

(54) High frequency semiconductor device

(75) Inventors: Kouken Yoshikawa, Shijonawate-shi (JP); Fumio Itoh, Nara-shi (JP)

Correspondence Address: EDWARDS & ANGELL, LLP, P.O. BOX 55874, BOSTON, MA, 02205, US

(73) Assignee: Sharp Kabushiki Kaisha, Osaka (JP)

(21) Appl. No.: 11/068,684

(22) Filed: Feb. 28, 2005

(30) Foreign Application Priority Data
Mar. 5, 2004 (JP) 2004-062685

(51) Int. Cl. H01L 21/44; H01L 23/06; H01L 23/52; H01L 29/00; H01L 21/48; H01L 23/34

(52) U.S. Cl. 257/684; 438/107; 257/724

(57) ABSTRACT

A high frequency semiconductor device including: at least two high frequency semiconductor chips each having an output electrode pad and a circuit; a frame having a die bond area in which the high frequency semiconductor chips are mounted; a plurality of leads which electrically connect the circuits of the respective high frequency semiconductor chips to an external device; and a plurality of output terminal connection wires connected between the output electrode pads of the respective chips and the corresponding leads, wherein the high frequency semiconductor chips are disposed in the die bond area with the output electrode pad of one of the high frequency semiconductor chips being spaced at least a first predetermined distance from the output electrode pad of the other high frequency semiconductor chip, and wherein the output terminal connection wire connected to the output electrode pad of the one high frequency semiconductor chip is spaced at least a second predetermined distance from the output terminal connection wire connected to the output electrode pad of the other high frequency semiconductor chip.

### CROSS-REFERENCE TO RELATED APPLICATION

This application is related to Japanese application No.2004-062685 filed on Mar. 5, 2004 whose priority is claimed under 35 USC §119, the disclosure of which is incorporated by reference in its entirety.

### BACKGROUND OF THE INVENTION

1. Field of the Invention

The present invention relates to a high frequency semiconductor device and, more specifically, to a high frequency semiconductor device which includes at least two semiconductor chips mounted in a die bond area thereof and adapted to output signals in different frequency bands.

2. Description of the Related Art

Transistors operative at high frequencies with high power outputs are essentially used as communication power amplifiers for personal computers, personal digital assistants and peripheral devices having wireless LAN capabilities. The transistors for this application utilize compound semiconductors to ensure excellent high frequency characteristics.

In recent years, a plurality of standards for different frequency bands have been utilized in combination to meet requirements for information transmission capacities, operating speeds and the like. To this end, a small-size high frequency semiconductor device including two semiconductor chips mounted in a single package and having different frequency bands for dual band applications has been developed for reduction of a mounting area in a product and for reduction of costs.

FIG. 10 is a diagram illustrating the inside of a dual-band high frequency semiconductor device of a conventional 2-chip package type and particularly illustrating the layout of chips in a die bond area of a frame and the routing of wires. As shown in FIG. 10, the die bond area 21 serves as a grounding electrode of the high frequency semiconductor device 26 in contact with rear electrodes (grounding electrodes) of high frequency semiconductor chips 22L, 22H. The semiconductor chip 22L (lower frequency chip) and the semiconductor chip 22H (higher frequency chip) for different frequency bands are disposed in juxtaposition in the die bond area 21, and electrode pads on the respective chips 22L and 22H are connected to leads (terminals) of a package by Au wires 25L and 25H.

Although a multiplicity of wires are provided in the device, only wires bonded to output leads of the device are shown in FIG. 10 for simplicity. In general, some of output terminals of the chips are each routed via a plurality of wires. This is because an inductance is reduced as the number of the wires is increased. Therefore, an output loss can be reduced by providing an increased number of wires.

A part of the semiconductor device 26 except the leads is packaged with a mold resin.

The conventional semiconductor device described above has the following problems.

FIGS. 2(a) and 2(b) are block diagrams schematically illustrating wireless LAN cards for a personal computer and particularly illustrating high frequency power amplifiers and filters.

In the wireless LAN card shown in FIG. 2(a), a harmonic signal from a lower frequency side (L-side) power amplifier 12L of a dual-band high frequency power amplifier 12 (corresponding to the high frequency semiconductor device 26 in FIG. 10) is essentially filtered away by a filter 14L. Where the conventional semiconductor device is used, however, the harmonic signal (particularly, a second harmonic signal) leaks through an output terminal of a higher frequency side (H-side) power amplifier 12H disposed in the vicinity of the L-side power amplifier 12L. Therefore, a signal containing a harmonic noise is transmitted from an antenna switch 16. Referring to FIG. 10, the harmonic signal is induced in an output signal line (i.e., an output electrode pad 24H and an output terminal connection wire 25H) of the chip 22H (corresponding to the H-side power amplifier 12H) from an output signal line (i.e., an output electrode pad 24L and an output terminal connection wire 25L) of the chip 22L (corresponding to the L-side power amplifier 12L), and leaks to be outputted as the noise.

In the wireless LAN card shown in FIG. 2(b), the conventional high frequency semiconductor device 12 further includes a switching element 13 for switching an output between the L-side power amplifier 12L and the H-side power amplifier 12H. However, the semiconductor device fails to meet the requirements for the size reduction and cost reduction of the device.

### SUMMARY OF THE INVENTION

In view of the foregoing, the present invention is directed to a high frequency semiconductor device which includes at least two semiconductor chips mounted in a die bond area thereof and adapted to output signals in different frequency bands, wherein an output electrode pad and a connection wire of one of the semiconductor chips are spaced at least a predetermined distance from an output electrode pad and a connection wire of the other semiconductor chip to suppress leak of a harmonic noise.

According to a first aspect of the present invention, there is provided a high frequency semiconductor device, which comprises at least two high frequency semiconductor chips each having an output electrode pad and a circuit, a frame having a die bond area in which the high frequency semiconductor chips are mounted, a plurality of leads which electrically connect the circuits of the respective high frequency semiconductor chips to an external device, and a plurality of output terminal connection wires connected between the output electrode pads of the respective chips and the corresponding leads, wherein the high frequency semiconductor chips are disposed in the die bond area with the output electrode pad of one of the high frequency semiconductor chips being spaced at least a first predetermined distance from the output electrode pad of the other high frequency semiconductor chip, and wherein the output terminal connection wire connected to the output electrode pad of the one high frequency semiconductor chip is spaced at least a second predetermined distance from the output terminal connection wire connected to the output electrode pad of the other high frequency semiconductor chip.

According to a second aspect of the present invention, there is provided a high frequency semiconductor device, which comprises at least two high frequency semiconductor chips each having an electrode pad, and a frame having a die bond area in which the high frequency semiconductor chips are mounted, wherein the die bond area has recesses in which the high frequency semiconductor chips are respectively disposed, the recesses each having a depth which is not smaller than 0.3 times a thickness of each of the high frequency semiconductor chips.

According to a third aspect of the present invention, there is provided a high frequency semiconductor device, which comprises at least two high frequency semiconductor chips each having an output electrode pad, and a frame having a die bond area in which the high frequency semiconductor chips are mounted, wherein the die bond area includes a wall provided between the high frequency semiconductor chips and having a height which is not smaller than 0.3 times a thickness of each of the high frequency semiconductor chips.

In the high frequency semiconductor device according to the first inventive aspect, the high frequency semiconductor chips are disposed in the die bond area with the output electrode pad of the one chip being spaced at least the first predetermined distance from the output electrode pad of the other chip, and the wire connected to the output electrode pad of the one high frequency semiconductor chip is spaced at least the second predetermined distance from the wire connected to the output electrode pad of the other high frequency semiconductor chip. Therefore, induction of a signal or a harmonic noise in a circuit of one of the chips from a circuit of the other chip via the chips or the wires is suppressed, thereby eliminating an influence of the harmonic noise.

In the high frequency semiconductor device according to the second inventive aspect, the high frequency chips are respectively disposed in the recesses of the die bond area each having a depth which is not smaller than 0.3 times the chip thickness. Therefore, induction of a signal or a harmonic noise in a circuit of one of the chips from a circuit of the other chip via the chips or wires is suppressed, thereby eliminating an influence of the harmonic noise.

In the high frequency semiconductor device according to the third inventive aspect, the die bond area includes the wall provided between the high frequency semiconductor chips and having a height which is not smaller than 0.3 times the chip thickness. Therefore, induction of a signal or a harmonic noise in a circuit of one of the chips from a circuit of the other chip via the chips or wires is suppressed, thereby eliminating an influence of the harmonic noise.

According to the present invention, there is also provided a high frequency semiconductor device comprising: at least two high frequency semiconductor chips each having a power amplifier, an output electrode pad and an output signal wiring connected between the output of the power amplifier and the output electrode pad; a frame having a die bond area in which the high frequency semiconductor chips are mounted; a plurality of leads which electrically connect the circuits of the respective high frequency semiconductor chips to an external device; and a plurality of output terminal connection wires connected between the output electrode pads of the respective chips and the corresponding leads, the output terminal connection wire constituting an output signal path together with the corresponding output signal wiring, the output electrode pad and the lead, wherein each output signal path is spaced at least a predetermined distance from other output signal path of the other high frequency semiconductor chip.

### BRIEF DESCRIPTION OF THE DRAWINGS

FIG. 1 is a schematic plan view illustrating a high frequency semiconductor device according to a first embodiment of the present invention in which electrode pads of different chips are spaced at least a predetermined distance from each other and wires connected to the electrode pads are spaced at least a predetermined distance from each other;

FIGS. 2(a) and 2(b) are block diagrams illustrating exemplary circuits to which the inventive high frequency semiconductor device is applicable;

FIGS. 3(a) and 3(b) are graphs of measurement results showing a relationship between leaked power and the distance between the output electrode pads, and a relationship between leaked power and the distance between the output terminal connection wires in the high frequency semiconductor device according to the first embodiment;

FIG. 4 is a schematic plan view illustrating a high frequency semiconductor device according to a second embodiment of the present invention in which two grounding leads and four grounding wires connected to the grounding leads are provided between output leads;

FIG. 5 is a graph of a measurement result showing a relationship between leaked power and the number of wires connected to the grounding leads provided between the output leads in the high frequency semiconductor device according to the second embodiment;

FIG. 6 is a schematic plan view illustrating a high frequency semiconductor device according to a third embodiment of the present invention in which chips are respectively mounted in recesses provided in a die bond area;

FIG. 7 is a sectional view taken along a line F-F′ in FIG. 6;

FIG. 8 is a schematic plan view illustrating a high frequency semiconductor device according to a fourth embodiment of the present invention in which a wall is provided between chips in a die bond area;

FIG. 9 is a sectional view taken along a line G-G′ in FIG. 8;

FIG. 10 is a schematic plan view illustrating the inside of a conventional high frequency semiconductor device; and

FIG. 11 is a sectional view of the conventional high frequency semiconductor device taken along a line H-H′ in FIG. 10.

### DETAILED DESCRIPTION OF THE INVENTION

A high frequency semiconductor device includes at least two high frequency semiconductor chips each having an output electrode pad and a circuit, a frame having a die bond area in which the high frequency semiconductor chips are mounted, a plurality of leads which electrically connect the circuits of the respective high frequency semiconductor chips to an external device, and a plurality of output terminal connection wires connected between the output electrode pads of the respective chips and the corresponding leads, wherein the high frequency semiconductor chips are disposed in the die bond area with the output electrode pad of one of the high frequency semiconductor chips being spaced at least a first predetermined distance from the output electrode pad of the other high frequency semiconductor chip, and wherein the output terminal connection wire connected to the output electrode pad of the one high frequency semiconductor chip is spaced at least a second predetermined distance from the output terminal connection wire connected to the output electrode pad of the other high frequency semiconductor chip.

The term “high frequency semiconductor chip” herein means a semiconductor chip which handles a signal having a frequency not lower than a megahertz band, particularly a semiconductor chip which handles a signal having a frequency in a gigahertz band. An HBT (heterojunction bipolar transistor) of a compound semiconductor is typically used for the gigahertz band semiconductor chip to ensure excellent frequency characteristics. Other exemplary transistors for the gigahertz band semiconductor chip include an MESFET (metal semiconductor field effect transistor) and an HEMT (high electron mobility transistor). For relatively low frequency applications, a silicon transistor may be used as long as it satisfies characteristic requirements.

The term “lead” herein means a terminal of a package of the high frequency semiconductor device. The high frequency semiconductor device is electrically connected to an external circuit via the leads. The leads are typically composed of Cu. Other exemplary materials for the leads include Cu alloys and Fe—Ni alloys such as a 42-alloy. In general, the frame is composed of the same material as the leads. Alternatively, the frame may be a ceramic case or a printed board. The term “die bond area” herein means an area of the frame on which the high frequency semiconductor chips are mounted and physically bonded. The term “wire” herein means an interconnection which electrically connects the electrode pad of the chip or the frame to the lead. Thin metal wires such as of gold or aluminum may be used as the wires.

The term “electrode pad” herein means an area of the chip through which the circuit in the chip is connected to the wire. The term “output electrode pad” is an electrode pad connected to an output of the circuit. The term “output terminal connection wire” herein means a wire connected to the output electrode pad. The expression “the output electrode pad of one of the high frequency semiconductor chip being spaced at least a first predetermined distance from the output electrode pad of the other high frequency semiconductor chip” herein means that the shortest distance between the output electrode pads of the respective chips (a linear distance between the closest portions of the output electrode pads of the chips) is not smaller than the first predetermined distance. Where the chips each include a plurality of output electrode pads, the shortest distance is a linear distance between the closest ones of the output electrode pads of the respective chips. The expression “the output terminal connection wire connected to the output electrode pad of the one high frequency semiconductor chip is spaced at least a second predetermined distance from the output terminal connection wire connected to the output electrode pad of the other high frequency semiconductor chip” herein means that the shortest distance between the output terminal connection wires (a linear distance between the closest portions of the respective output terminal connection wires) is not smaller than the second predetermined distance.

The shortest distance between the output electrode pads of the respective high frequency semiconductor chips may be not smaller than 1.0 mm. Thus, induction of a signal or a harmonic noise in the circuit of one of the chips from the circuit of the other chip can effectively be suppressed. The shortest distance between the output electrode pads of the respective high frequency semiconductor chips is preferably not smaller than 1.3 mm.

The die bond area may have a rectangular shape, and the two high frequency semiconductor chips may be disposed on a diagonal line of the rectangular die bond area. Thus, the two chips are spaced a greater distance from each other, so that induction of a signal or a harmonic noise in the circuit of one of the chips from the circuit of the other chip can more effectively be suppressed.

The shortest distance between the output terminal connection wire connected to the output electrode pad of the one high frequency semiconductor chip and the output terminal connection wire connected to the output electrode pad of the other high frequency semiconductor chip may be not smaller than 0.8 mm. Thus, induction of a signal or a harmonic noise in the circuit of one of the chips from the circuit of the other chip is effectively suppressed. The shortest distance between the output terminal connection wires connected to the output electrode pads of the respective chips is preferably not smaller than 1.0 mm.

The leads include grounding leads connected to grounding wires connected to the frame, and output leads connected to the output terminal connection wires. At least two grounding wires may be provided between an output lead connected to the output electrode pad of the one high frequency semiconductor chip and an output lead connected to the output electrode pad of the other high frequency semiconductor chip. Thus, induction of a signal or a harmonic noise in the circuit of one of the chips from the circuit of the other chip can be suppressed by the grounding leads and the at least two grounding wires provided between the output leads. The number of the grounding wires is preferably three or greater, more preferably four or greater.

### DESCRIPTION OF THE PREFERED EMBODIMENTS

With reference to the attached drawings, the present invention will hereinafter be described in detail by way of embodiments thereof.

### First Embodiment

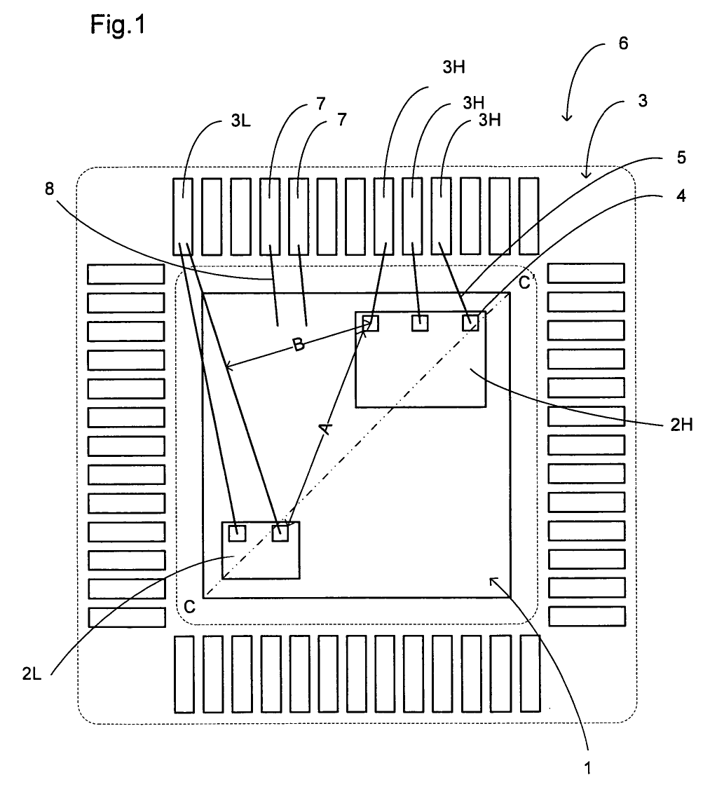

FIG. 1 is a schematic plan view illustrating a high frequency semiconductor device according to a first embodiment of the present invention in which electrode pads of chips thereof are spaced at least a predetermined distance from each other and wires thereof connected to the electrode pads are spaced at least a predetermined distance from each other.

As shown in FIG. 1, the high frequency semiconductor device 6 includes two high frequency semiconductor chips 2H, 2L mounted in a die bond area 1 of a frame thereof. In this embodiment, the frame has a thickness of 0.15 mm by way of example. Output electrode pads 4 of the high frequency semiconductor chip 2H are electrically connected to an external circuit provided outside the high frequency semiconductor device 6 via output terminal connection wires 5 and leads 3H. The high frequency semiconductor chips 2H, 2L shown in FIG. 1 each include a plurality of output electrode pads (in FIG. 1, not all the output electrode pads are denoted by reference characters). In some cases, the high frequency semiconductor chips each include a single output electrode pad. The output electrode pads of the chip 2L are connected to a lead 3L via output terminal connection wires. The high frequency semiconductor device 6 includes a plurality of leads 3, and the leads 3H, 3L are particular ones of the leads 3.

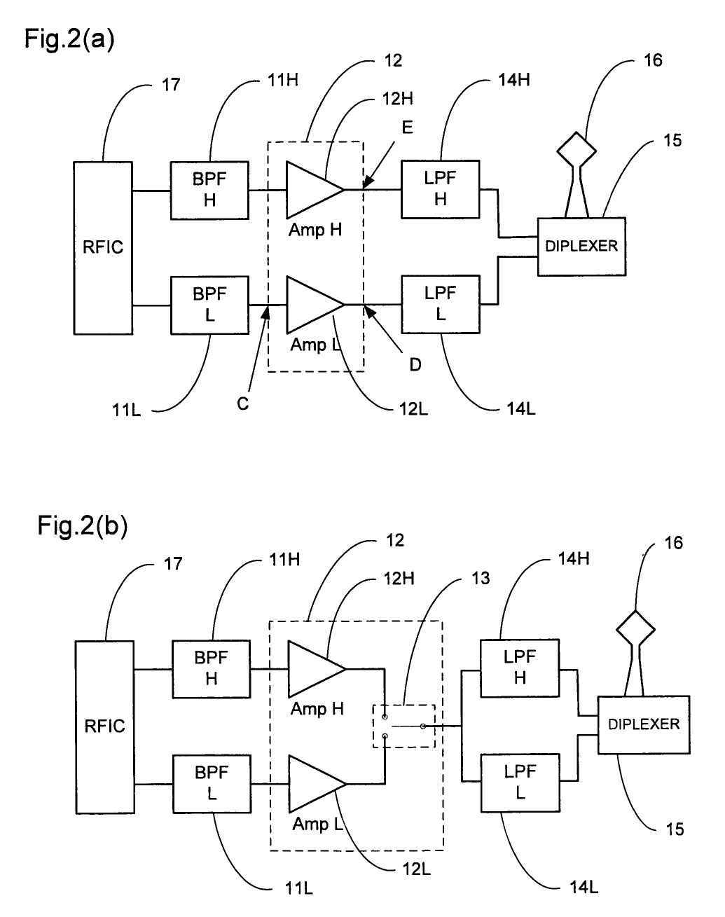

FIGS. 2(a) and 2(b) are block diagrams illustrating exemplary circuits to which the inventive high frequency semiconductor device is applicable. In the block diagrams shown in FIGS. 2(a) and 2(b), high frequency semiconductor devices 12 each include a higher frequency band amplifier 12H and a lower frequency band amplifier 12L for different frequency bands. The lower frequency band amplifier 12L and the higher frequency band amplifier 12H respectively correspond to the chips 2L and 2H of the high frequency semiconductor device 6 in FIG. 1. The high frequency semiconductor device 12 is a dual-band high frequency semiconductor device in which the lower frequency band amplifier 12L amplifies a 2.4 GHz signal and the higher frequency band amplifier 12H amplifies a 5 GHz signal. The amplifiers 12L, 12H each include an HBT (heterojunction bipolar transistor) of a compound semiconductor.

In the circuit shown in FIG. 2(a), an RFIC 17 having an RF circuit outputs a 2.4 GHz (lower frequency band) signal or a 5 GHz (higher frequency band) signal according to device use conditions. The higher frequency band signal is passed through a band pass filter 11H and the amplifier 12H to be amplified, and the amplified higher frequency band signal is passed through a low pass filter 14H and a diplexer 15 and outputted from an antenna 16. The outputted higher frequency band signal is received by a receiver not shown, and demodulated to provide information. Similarly, the lower frequency band signal is passed through a band pass filter 11L, the amplifier 12L, a low pass filter 14L and the diplexer 15, and outputted from the antenna 16. The band pass filters 11H, 11L and the low pass filters 14H, 14L have different frequency characteristics for the signals of the different frequency bands.

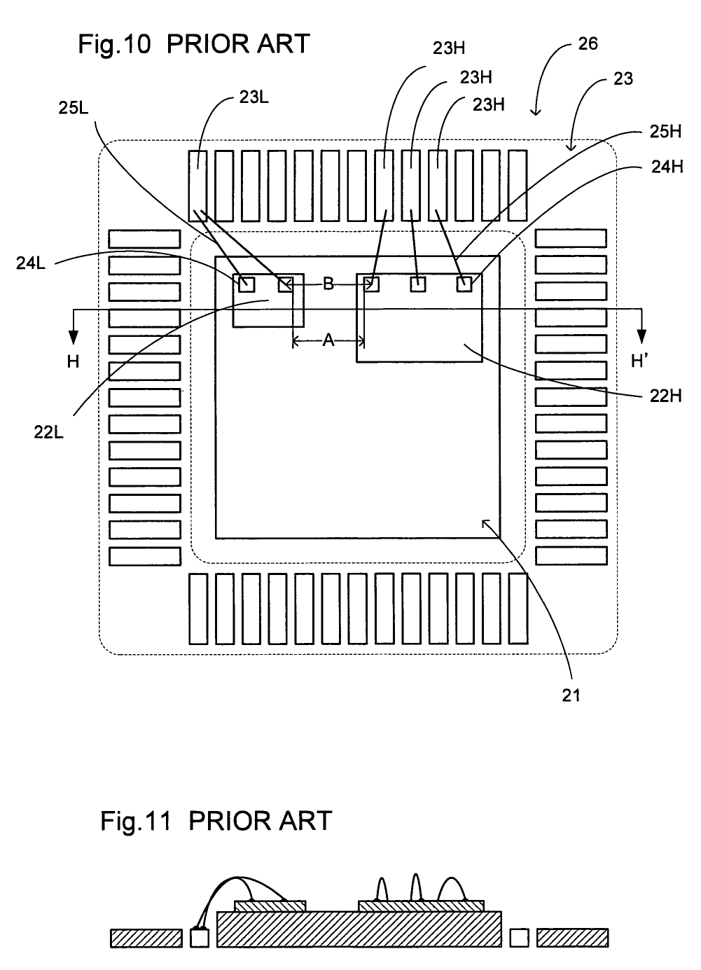

As shown in FIG. 1, the high frequency semiconductor chip 2L for the lower frequency band amplifier (2.4 GHz) and the high frequency semiconductor chip 2H for the higher frequency band amplifier (5 GHz) are disposed on a diagonal line C-C′ in the die bond area 1 in the high frequency semiconductor device 6. In the conventional high frequency semiconductor device 26 shown in FIG. 10, the high frequency semiconductor chip 22L for the lower frequency band amplifier (2.4 GHz) and the high frequency semiconductor chip 22H for the higher frequency band amplifier (5 GHz) are disposed alongside one edge of the die bond area 21. In FIGS. 1 and 10, the shortest distances between the output electrode pads of the chips are denoted by a reference character A. Since the chips are disposed on the diagonal line in the die bond area in the high frequency semiconductor device 6 shown in FIG. 1, the output electrode pads of the two chips are spaced a greater distance from each other than in the conventional high frequency semiconductor device 26. Where the package has a size of 4 mm square and the chips 2H, 2L mounted in the die bond area 1 respectively have sizes of 1 mm square and 0.7 mm square, the distance between the output electrode pads of the respective chips disposed on the diagonal line in the die bond area in the inventive high frequency semiconductor device 6 is 1.3 mm. On the other hand, the distance between the output electrode pads of the respective chips not disposed on the diagonal line in the die bond area in the conventional high frequency semiconductor device 26 is 0.5 mm. In this embodiment, therefore, the distance between the output electrode pads is more than doubled as compared with the prior art.

The output terminal connection wires are routed so that the shortest distance between the output terminal connection wires indicated by a reference character B in FIG. 1 is not smaller than a predetermined distance. In FIG. 1, the output terminal connection wires from the lower frequency band chip 2L which is less likely to influence the device characteristics are connected to the single lead 3L so as to increase the distance from the closest wire of the higher frequency band chip 2H. However, it is difficult to reduce the number of the leads for the higher frequency band chip 2H which is more likely to influence the device characteristics.

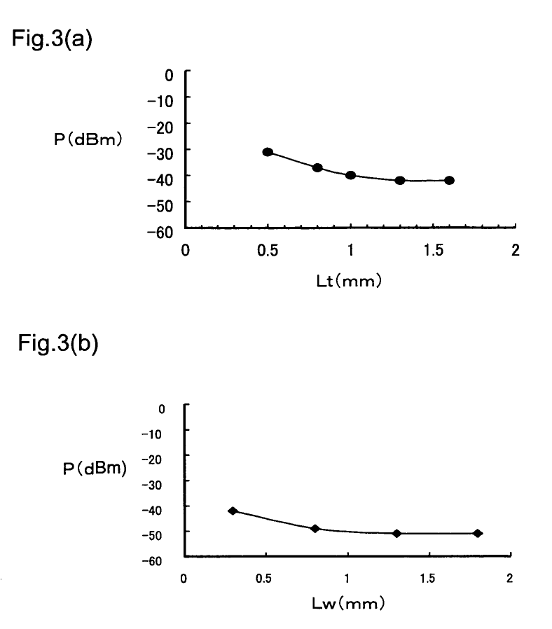

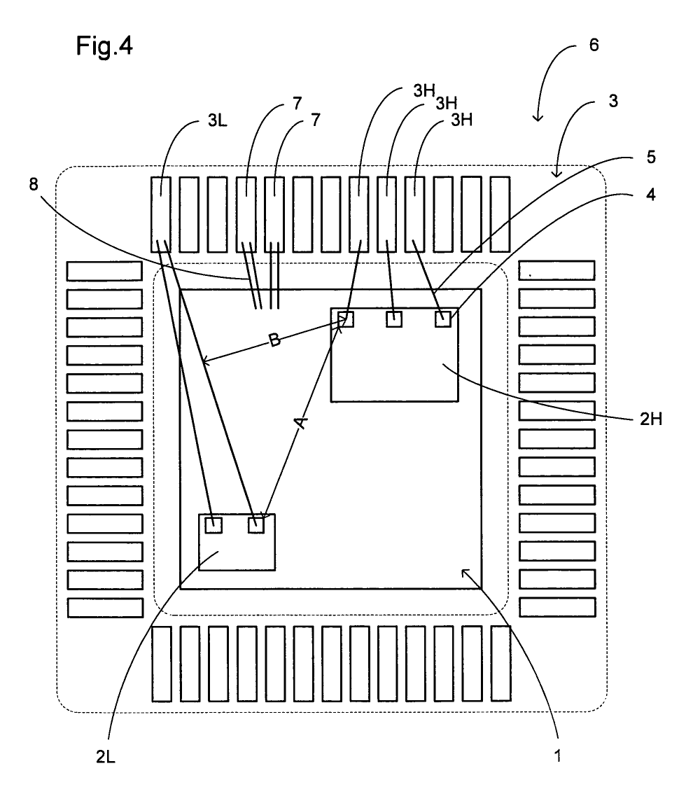

FIG. 3(a) is a graph of the result of measurement showing a relationship between leaked power P and a distance Lt between the output electrode pads in the high frequency semiconductor device according to this embodiment. In the measurement, a measurement signal of a frequency of 2.35 to 2.55 GHz was input to an input terminal C of the lower frequency band amplifier 12L shown in FIG. 2(a), and the leaked power was measured at an output terminal E of the higher frequency band amplifier 12H by adjusting the amplitude of the input signal so as to provide an output of 23 dB at an output terminal D of the lower frequency band amplifier 12L. A spectrum analyzer MS2687B available from Anritsu Co., Ltd. was used for the measurement. When the output electrode pads of the respective chips 2H, 2L disposed on the diagonal line in the die bond area 1 were spaced a distance of not smaller than 1.0 mm from each other, as described above, the power leaked to the higher frequency band circuit was reduced from −31 dBm to −40 dBm. Thus, an improvement of 9 dBm was observed. Further, when the output electrode pads of the respective chips 2H, 2L were spaced a distance of not smaller than 1.3 mm from each other, the power leaked to the higher frequency band circuit was reduced from −31 dBm to −42 dBm. Thus, an improvement of not smaller than 10 dBm was observed. In this measurement, two leads 7 disposed between the output leads for the chips are respectively grounded via wires 8 (25 μmφ gold wires). An effect provided by the grounding will be described in a second embodiment.

FIG. 3(b) is a graph of the result of measurement showing a relationship between leaked power P and a distance Lw between the output terminal connection wires in the high frequency semiconductor device according to this embodiment. In the measurement, the output electrode pads of the respective chips were spaced a distance of not smaller than 1.3 mm from each other, and the output terminal connection wires connected to the respective chips were spaced a distance of not smaller than 0.8 mm from each other. As shown, an improvement was observed such that the leaked power was reduced by 7 dBm. When the output terminal connection wires connected to the respective chips were spaced a distance of not smaller than 1 mm from each other, an improvement was observed such that the leaked power was reduced by 9 dBm.

It was confirmed that the power leaked to the higher frequency band circuit is reduced by spacing the output electrode pads of the respective chips a distance of not smaller than 1.0 mm from each other. It was also confirmed that the leaked power reducing effect is improved by spacing the output terminal connection wires connected to the respective chips a distance of not smaller than 0.8 mm from each other. When the output electrode pads of the respective chips were spaced a distance of not smaller than 1.3 mm from each other and the output terminal connection wires connected to the respective chips were spaced a distance of not smaller than 1.0 mm from each other, power leaked from the lower frequency band amplifier 2L to the higher frequency band amplifier 2H was reduced to not higher than −50 dBm. By thus increasing the distance between the output electrode pads and the distance between the output terminal connection wires, the influence of the leaked power is reduced to a virtually negligible level.

### Second Embodiment

FIG. 4 is a schematic plan view illustrating a high frequency semiconductor device in which grounding leads and grounding wires are provided between output leads according to this embodiment of the present invention. As shown, leads 7 present between output leads respectively connected to two different chips (a lower frequency band amplifier 2L and a higher frequency band amplifier 2H) are each grounded via two or more wires 8 (25 μmφ gold wires). In FIG. 4, two leads 7 are each grounded via two wires 8, so that a total of four wires 8 are used for the grounding.

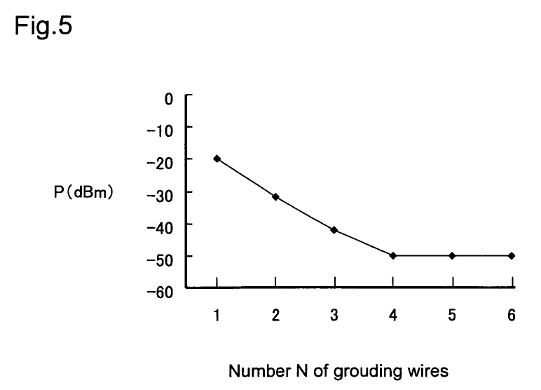

FIG. 5 is a graph of the result of measurement showing a relationship between leaked power P and the number of wires connected to the grounding leads provided between the output leads in the high frequency semiconductor device according to this embodiment. The measurement was performed in the same manner as in the first embodiment. By grounding the leads present between the output terminals of the respective chips via two or more grounding wires, a harmonic noise occurring due to interference between the chips or between the wires is grounded. As shown in the graph of FIG. 5, power leaked from the lower frequency band amplifier 2L to the higher frequency band amplifier 2H was reduced from about −20 dBm to not greater than −30 dBm. That is, the harmonic noise was reduced by not smaller than 10 dBm. When the number N of the grounding wires was three, the leaked power was reduced to not greater than −40 dBm. When the number N of the grounding wires was four or greater, the leaked power was reduced to not greater than −50 dBm.

### Third Embodiment

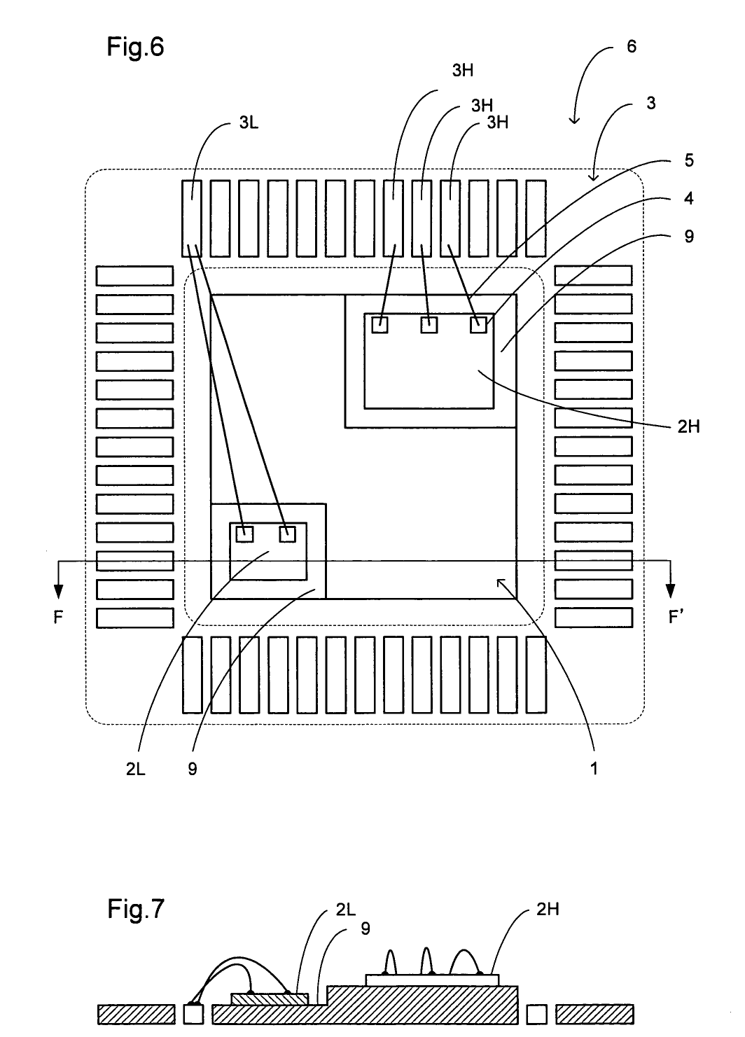

FIG. 6 is a schematic plan view illustrating a high frequency semiconductor device 6 according to a third embodiment of the present invention in which chips are respectively mounted in recesses provided in a die bond area. FIG. 7 is a sectional view taken along a line F-F′ in FIG. 6. A comparison with the schematic plan view of the conventional high frequency semiconductor device 26 shown in FIG. 10 and a sectional view taken along a line H-H′ in FIG. 10 facilitates the understanding of this embodiment. As shown in FIGS. 6 and 7, recesses 9 each having a depth of 150 μm which is about 1.5 times a chip thickness are provided in a die bond area, and a lower frequency band amplifier (chip) 2L and a higher frequency band amplifier (chip) 2H are respectively die-bonded in the recesses 9. Therefore, the chips are shielded from each other. Thus, a harmonic noise (second harmonic signal) leaked from the lower frequency band amplifier 2L to the higher frequency band amplifier 2H is reduced.

It was experimentally confirmed that recesses each having a depth of not smaller than 30 μm which is not smaller than 0.3 times the chip thickness are effective for the reduction of the harmonic noise.

### Fourth Embodiment

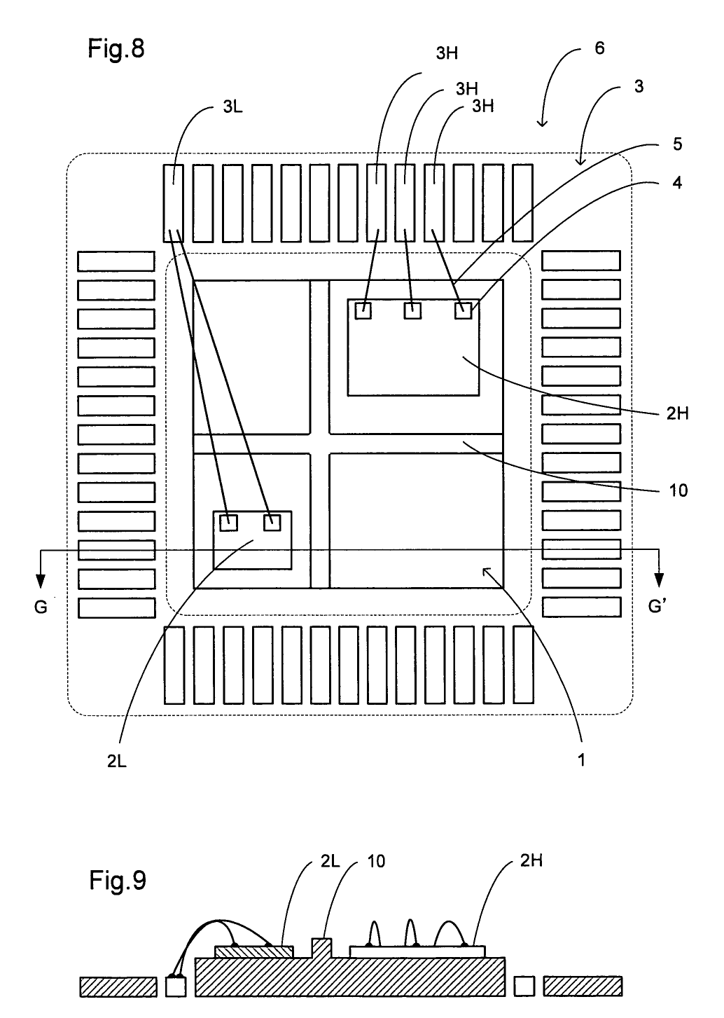

FIG. 8 is a schematic plan view illustrating a high frequency semiconductor device 6 according to a fourth embodiment of the present invention in which a wall is provided between chips in a die bond area. FIG. 9 is a sectional view taken along a line G-G′ in FIG. 8. As shown in FIGS. 8 and 9, a wall 10 having a height of 150 μm which is about 1.5 times a chip thickness is provided between a lower frequency band amplifier (chip) 2L and a higher frequency band amplifier (chip) 2H in a die bond area, whereby the chips are shielded from each other. Thus, a harmonic noise (second harmonic signal) leaked from the lower frequency band amplifier 2L to the higher frequency band amplifier 2H can be reduced as in the third embodiment.

It was experimentally confirmed that a wall having a height of not smaller than 30 μm which is not smaller than 0.3 times the chip thickness is effective for the reduction of the harmonic noise.

The first to fourth embodiments may be employed either alone or in combination to provide the inventive high frequency semiconductor devices.

1. A high frequency semiconductor device comprising:
at least two high frequency semiconductor chips each having an output electrode pad and a circuit;
a frame having a die bond area in which the high frequency semiconductor chips are mounted;
a plurality of leads which electrically connect the circuits of the respective high frequency semiconductor chips to an external device; and
a plurality of output terminal connection wires connected between the output electrode pads of the respective chips and the corresponding leads,
wherein the high frequency semiconductor chips are disposed in the die bond area with the output electrode pad of one of the high frequency semiconductor chips being spaced at least a first predetermined distance from the output electrode pad of the other high frequency semiconductor chip,
and wherein the output terminal connection wire connected to the output electrode pad of the one high frequency semiconductor chip is spaced at least a second predetermined distance from the output terminal connection wire connected to the output electrode pad of the other high frequency semiconductor chip.

2. A high frequency semiconductor device of claim 1, wherein the first predetermined distance is not smaller than 1.0 mm.

3. A high frequency semiconductor device of claim 1,
wherein the die bond area has a rectangular shape,
and wherein the two high frequency semiconductor chips are disposed on a diagonal line of the rectangular die bond area.

4. A high frequency semiconductor device of claim 1, wherein the second predetermined distance is not smaller than 0.8 mm.

5. A high frequency semiconductor device of claim 1,
wherein the leads include grounding leads connected to grounding wires connected to the frame, and output leads connected to the output terminal connection wires,
and wherein at least two grounding wires are provided between an output lead connected to the output electrode pad of the one high frequency semiconductor chip and an output lead connected to the output electrode pad of the other high frequency semiconductor chip.

6. A high frequency semiconductor device comprising:
at least two high frequency semiconductor chips each having an electrode pad; and
a frame having a die bond area in which the high frequency semiconductor chips are mounted,
wherein the die bond area has recesses in which the high frequency semiconductor chips are respectively disposed, the recesses each having a depth which is not smaller than 0.3 times a thickness of each of the high frequency semiconductor chips.

7. A high frequency semiconductor device comprising:
at least two high frequency semiconductor chips each having an output electrode pad; and
a frame having a die bond area in which the high frequency semiconductor chips are mounted,
wherein the die bond area includes a wall provided between the high frequency semiconductor chips and having a height which is not smaller than 0.3 times a thickness of each of the high frequency semiconductor chips.

8. A high frequency semiconductor device comprising:
at least two high frequency semiconductor chips each having a power amplifier, an output electrode pad and an output signal wiring connected between the output of the power amplifier and the output electrode pad;
a frame having a die bond area in which the high frequency semiconductor chips are mounted;
a plurality of leads which electrically connect the circuits of the respective high frequency semiconductor chips to an external device; and
a plurality of output terminal connection wires connected between the output electrode pads of the respective chips and the corresponding leads, the output terminal connection wire constituting an output signal path together with the corresponding output signal wiring, the output electrode pad and the lead,
wherein each output signal path is spaced at least a predetermined distance from other output signal path of the other high frequency semiconductor chip.
